(19) United States
(12) Patent Application Publication
(10) Pub. No.: US 2025/0160226 A1
(43) Pub. Date: May 15, 2025

(54) RRAM STRUCTURE AND FABRICATING METHOD OF THE SAME

(71) Applicant: UNITED MICROELECTRONICS CORP, Hsin-Chu City (TW)

(72) Inventors: Wen-Jen Wang, Tainan City (TW); Yu-Huan Yeh, Taichung City (TW); Chuan-Fu Wang, Miaoli County (TW)

(73) Assignee: UNITED MICROELECTRONICS CORP, Hsin-Chu City (TW)

(21) Appl. No.: 18/531,722

(22) Filed: Dec. 7, 2023

(30) Foreign Application Priority Data
Nov. 14, 2023 (TW) 112143766

(51) Int. Cl. H10N 70/00; H10B 63/00

(52) U.S. Cl. CPC H10N 70/8833; H10B 63/80; H10N 70/021; H10N 70/821; H10N 70/841

(57) ABSTRACT

An RRAM structure includes an RRAM. The RRAM includes a bottom electrode, a variable resistive layer and a top electrode stacked from bottom to top, wherein the bottom electrode is composed of titanium oxide (TiOₓ), 0<x≤2, and x has a gradient variation increased toward the top electrode.

### BACKGROUND OF THE INVENTION

### 1. Field of the Invention

The present invention relates to a resistive random access memory (RRAM) structure and a manufacturing method thereof, and in particular to a structure with the ratio of oxygen atoms in a bottom electrode has a gradient variation and a manufacturing method thereof.

### 2. Description of the Prior Art

Nonvolatile memory is capable of retaining the stored information even when unpowered. Non-volatile memory may be used for secondary storage or long-term persistent storage. RRAM technology has been gradually recognized as having exhibited those semiconductor memory advantages.

RRAM cells are non-volatile memory cells that store information by changes in electric resistance, not by changes in charge capacity. In general, the resistance of the resistive switching layer varies according to an applied voltage. An RRAM cell can be in a plurality of states in which the electric resistances are different. Each different state may represent a digital information. The state can be changed by applying a predetermined voltage or current between the electrodes. A state is maintained as long as a predetermined operation is not performed.

However, generally, when manufacturing the bottom electrode of an RRAM, numerous deposition processes are required, which makes the process time long.

### SUMMARY OF THE INVENTION

In view of this, the present invention adjusts the oxygen concentration inputted during a deposition process so that the atom ratio of oxygen atoms in the bottom electrode changes in a gradient. In this way, processing steps can be reduced.

According to a preferred embodiment of the present invention, an RRAM structure includes an RRAM, wherein the RRAM includes a bottom electrode, a variable resistive layer and a top electrode stacked from bottom to top, wherein the bottom electrode is composed of titanium oxide (TiOₓ), and x has an increased gradient variation which is increased toward the top electrode.

According to another preferred embodiment of the present invention, a fabricating method of an RRAM structure includes forming an RRAM, wherein the RRAM includes a bottom electrode, a variable resistive layer and a top electrode stacked from bottom to top, wherein the bottom electrode is composed of titanium oxide (TiOₓ), and x has an increased gradient variation which is increased toward the top electrode.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 5 depict a fabricating method of an RRAM structure according to a preferred embodiment of the present invention, wherein:

FIG. 1 depicts a dielectric layer with conductive lines embedded therein;

FIG. 2 is a fabricating stage in continuous of FIG. 1;

FIG. 3 is a fabricating stage in continuous of FIG. 2;

FIG. 4 is a fabricating stage in continuous of FIG. 3; and

FIG. 5 is a fabricating stage in continuous of FIG. 4.

FIG. 6 depicts a variation of x between a bottom surface and a top surface of a bottom electrode according to a preferred embodiment of the present invention.

FIG. 7 depicts a variation of x between a bottom surface and a top surface of a bottom electrode according to another preferred embodiment of the present invention.

FIG. 8 depicts a variation of x between a bottom surface and a top surface of a bottom electrode according to yet another preferred embodiment of the present invention.

FIG. 9 depicts schematically a conventional RRAM.

FIG. 10 depicts a variation of n between a bottom surface and a top surface of a bottom electrode.

### DETAILED DESCRIPTION

FIG. 1 to FIG. 5 depict a fabricating method of an RRAM structure according to a preferred embodiment of the present invention.

As shown in FIG. 1, a first dielectric layer 10 is provided, and at least one conductive line 12 is disposed in the first dielectric layer 10. In FIG. 1, two conductive lines 12 are shown as an example. Next, an etching stop layer 14 is formed to cover the first dielectric layer 10. Then, a second dielectric layer 16 is formed to cover the etching stop layer 14. Thereafter, a patterned mask (not shown) is formed to cover the second dielectric layer 16. After that, the second dielectric layer 16 and the etching stop layer 14 are etched to form a contact hole 18 penetrating the second dielectric layer 16 and the etching stop layer 14 by taking the patterned mask as a mask. Now, the conductive line 12 is exposed through the contact hole 18.

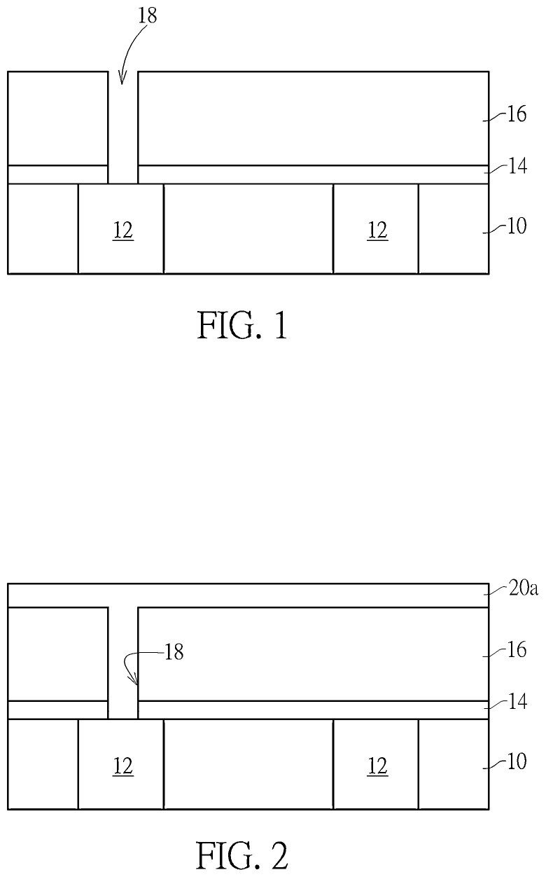

As shown in FIG. 2, a titanium layer 20a is formed to fill the contact hole 18 and cover the top surface of the second dielectric layer 16. The titanium layer 20a can be formed by a physical vapor deposition, a chemical vapor deposition or an atomic layer deposition. Later, the titanium layer 20a is planarized by a chemical mechanical planarization process.

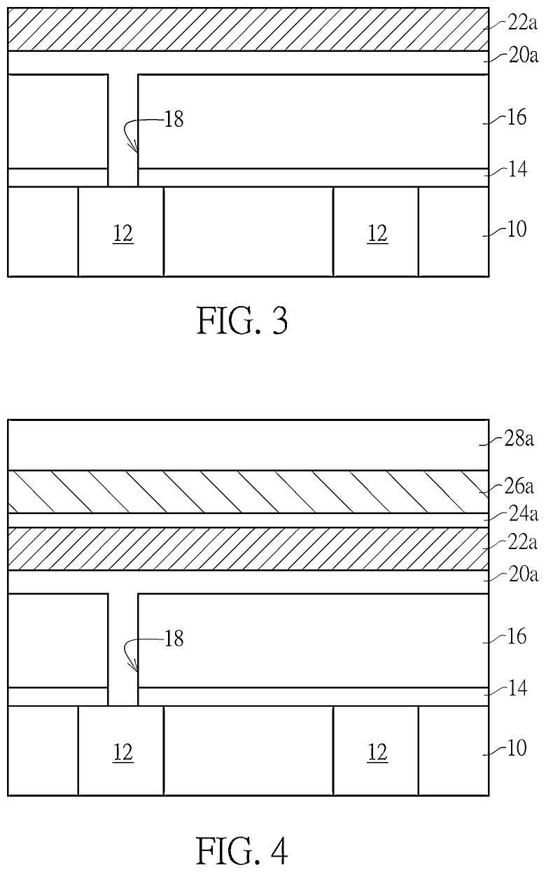

As shown in FIG. 3, a bottom electrode material layer 22a is formed to cover the titanium layer 20a. The bottom electrode material layer 22a is composed of titanium oxide (TiOₓ). X is the ratio of oxygen atoms to titanium atoms in titanium oxide. According to a preferred embodiment of the present invention, 0<x≤2, and x has an increased gradient variation which increased in a direction away from the titanium layer 20a. The increased gradient variation is increased in a continuous manner, and the increased gradient variation is increased in a unit that is not an integer. The formation method of the bottom electrode material layer 22a may be formed by a physical vapor deposition, a chemical vapor deposition or an atomic layer deposition. During the deposition, titanium is used as a target which is bombarded by inert gas, and oxygen is input into chamber to react with titanium to form titanium oxide. The flow rate of oxygen gas increases as the operation time of the deposition passes by. That is, the flow rate of oxygen shows an increased gradient variation as the operation time of the deposition increases. The deposition of titanium oxide stops when the ratio of oxygen atoms to titanium atoms in titanium oxide is equal to 2, that is, x=2. In this way, the bottom electrode material layer 22a can be formed. In addition, oxygen is continuously input into the chamber during the deposition, and the bombardment of inert gas is not stopped during the deposition. Therefore, the bottom electrode material layer 22a is formed by using only one deposition process.

As shown in FIG. 4, a variable resistive layer 24a, a top electrode material layer 26a and a mask layer 28a are sequentially formed to cover the bottom electrode material layer 22a. The variable resistive layer 24a is preferably tantalum oxide or hafnium oxide. The top electrode material layer 26a is preferably titanium nitride or tantalum nitride. The mask layer 28a is preferably silicon oxide or silicon oxynitride.

As shown in FIG. 5, the mask layer 28a is patterned to form a mask layer 28. Later, by using the mask layer 28 as a mask, the top electrode material layer 26a, the variable resistive material layer 24a, the bottom electrode material layer 22a and the titanium layer 20a are etched to form an RRAM 100 and a titanium plug 20 disposed under the RRAM 100. After etching, the top electrode material layer 26a becomes a top electrode 26, the variable resistive material layer 24a becomes a variable resistive layer 24, the bottom electrode material layer 22a becomes a bottom electrode 22, and the titanium layer 20a becomes a titanium plug 20. The bottom electrode 22, the variable resistive layer 24 and the top electrode 26 form the RRAM 100 of the present invention. Now, the RRAM 100 of the present invention is completed. As mentioned above, because the bottom electrode material layer 22a is formed by using only one deposition process, the bottom electrode 22 is formed monolithically.

As shown in FIG. 5, an RRAM structure 300 includes an RRAM 100. The RRAM 100 includes a bottom electrode 22, a variable resistive layer 24 and a top electrode 26 stacked from bottom to top. The bottom electrode 22 is composed of titanium oxide (TiOₓ), and 0<x≤2. X has an increased gradient variation which is increased toward the top electrode 26. In other words, the value of x is different at each position along the direction toward the top electrode 26. X is the ratio of oxygen atoms to titanium atoms in titanium oxide. The bottom electrode 22 has a bottom surface 22b and a top surface 22t, and the bottom surface 22b contacts the titanium plug 20. The top surface 22t contacts the variable resistive layer 24. According to a preferred embodiment of the present invention, the bottom electrode 22 is formed by stacking more than 100 layers of titanium oxide, and the value of x in each layer of titanium oxide is different.

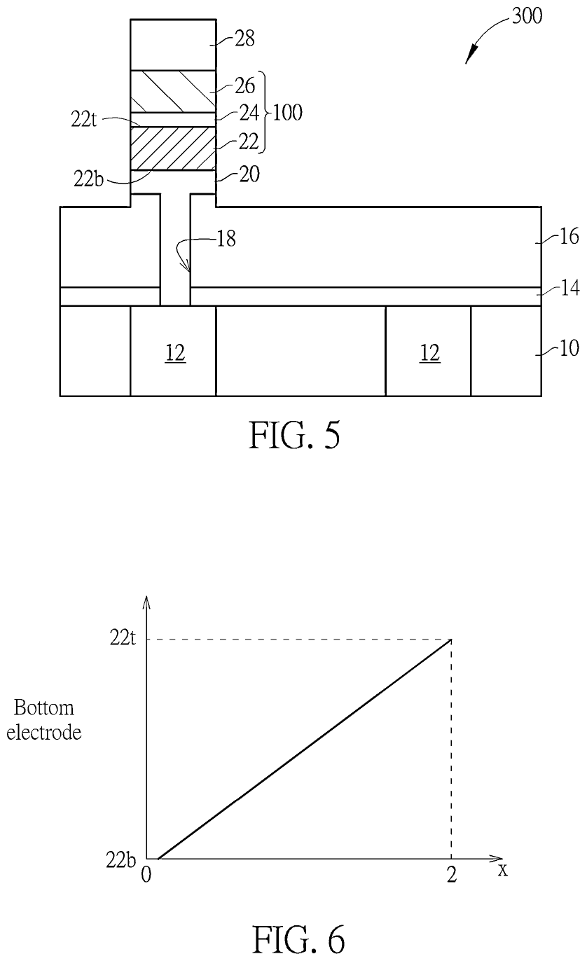

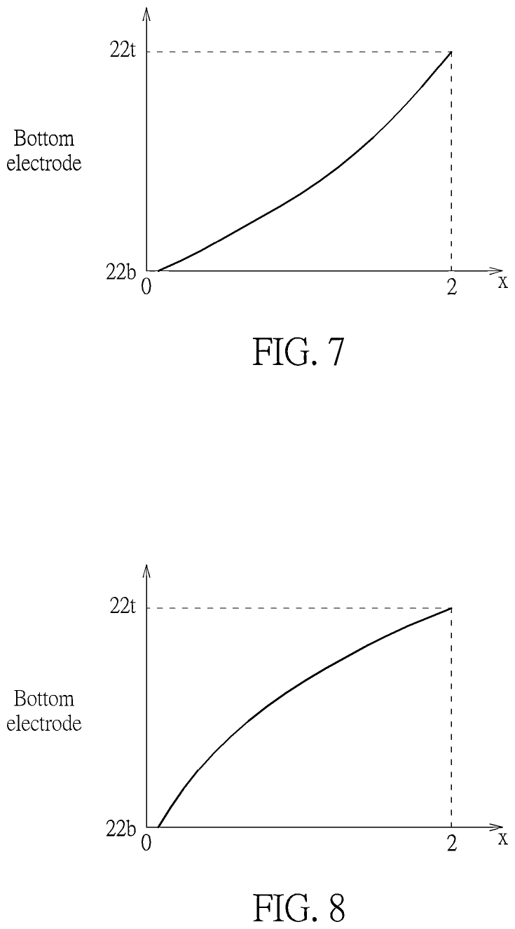

FIG. 6 to FIG. 8 depict a variation of x between the bottom surface 22b and the top surface 22t of the bottom electrode 22. As shown in FIG. 6, 0<x≤2. The gradient variation of x in the direction along the bottom surface 22b to the top surface 22t is linear, increased and continuous. Furthermore, there is no abrupt change of x. As shown in FIG. 7, 0<x≤2. The gradient variation of x in the direction along the bottom surface 22b to the top surface 22t is curved, increased and continuous. The curve of the gradient variation is concaved up. Similarly, there is no abrupt change of x. As shown in FIG. 8, 0<x≤2. The gradient variation of x in the direction along the bottom surface 22b to the top surface 22t is curved, increased and continuous. The curve of the gradient variation is concaved down. There is no abrupt change of x as well.

Moreover, a composition of the bottom electrode 22 along a direction toward the top electrode 26 is nonhomogeneous. The gradient variation of x is increased in a unit that is not an integer. That is, x changed in a unit which is not an integer. For example, the gradient variation of x along the direction toward the top electrode 26 may start from x equaling 0.1, then x increasing to 0.2. After that, x increases to 0.3, and x increases until x equals 2. In this example, x changed in a unit that is 0.1.

Please refer to FIG. 5 again. A second dielectric layer 16 is disposed under the RRAM 100, and a titanium plug 20 is embedded in the second dielectric layer 16. The titanium plug 20 is T-shaped, and the vertical part of the T-shaped is filled in the contact hole 18. The lateral part of the T-shape is disposed outside of the contact hole 18, on the second dielectric layer 16 and in direct contact with the second dielectric layer 16. The lateral part of the T-shape of the titanium plug 20 directly contacts the bottom electrode 22. An etching stop layer 14 and a first dielectric layer 10 are disposed below the second dielectric layer 16. A conductive line 12 is embedded in the first dielectric layer 10, and the conductive layer 12 contacts the titanium plug 20. Furthermore, a switching element (not shown), such as a transistor, may be disposed under the first dielectric layer 10. The transistor can electrically connect to the bottom electrode 22 of the RRAM 100 through the conductive line 12. The top electrode 26 of the RRAM 100 connects to another conductive line (not shown) so as to form external connection. When applying bias voltage to the bottom electrode 22 and the top electrode 26, filaments are formed in the variable resistive layer 24. Part of filaments may extend to the bottom electrode 22. In this way, a forming process of the RRAM 100 can be completed.

According to a preferred embodiment of the present invention, the variable resistive layer 24 includes tantalum oxide or hafnium oxide. The top electrode 26 includes titanium nitride or tantalum nitride. The etching stop layer 14 is preferably nitrogen-doped silicon carbide (NDC). The first dielectric layer 10 and the second dielectric layer 16 can be silicon oxide or silicon oxynitride.

As shown in FIG. 9, a conventional RRAM 200 is shown. The bottom electrode 122 is formed by three material layers 122i/122j/122k. The bottom electrode 122 has a top surface 122t and a bottom surface 122b. The top surface 122t contacts the variable resistive layer 124. The bottom surface 122b may contact a conductive plug (not shown). A top electrode 126 is disposed on the variable resistive layer 124. There is an interface between the three material layers 122i/122j/122k, such as an interface a and an interface b. The deposition process of each of the three material layers 122i/122j/122k includes steps of turning off input gas and turning on input gas again. Each of the three material layers 122i/122j/122k is homogenous in the direction toward the top electrode 126. For example, from the bottom surface 122b of the bottom electrode 122 toward the interface a, the composition of the material layer 122i is fixed and homogeneous. In the direction from interface a to interface b, the composition of the material layer 122j is fixed and homogeneous. The composition of the material layer 122k is fixed and homogeneous in the direction from interface a to interface b. The number of material layers in the bottom electrode 122 of the conventional RRAM 200 is small, and is usually composed of less than three material layers.

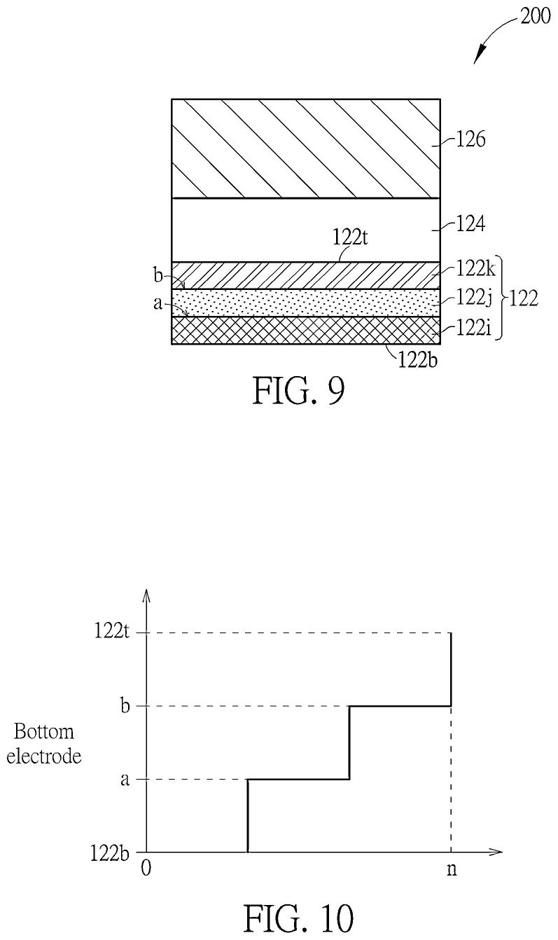

As shown in FIG. 10, The material of the bottom electrode 122 is metal oxide (MOₙ), and n>0. M represents metal atom. The variation in n from the bottom surface 122b to the top surface 122t is increased in a step profile. That is, at some position of the bottom electrode 122, the value of n is fixed.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A resistive random access memory (RRAM) structure comprising:
an RRAM, wherein the RRAM comprises a bottom electrode, a variable resistive layer and a top electrode stacked from bottom to top, wherein the bottom electrode is composed of titanium oxide (TiOₓ), and x has an increased gradient variation which is increased toward the top electrode.

2. The RRAM structure of claim 1, wherein the increased gradient variation is increased in a unit that is not an integer.

3. The RRAM structure of claim 1, wherein the increased gradient variation is increased in a continuous manner.

4. The RRAM structure of claim 1, wherein the increased gradient variation is increased linearly or curvedly.

5. The RRAM structure of claim 1, wherein a composition of the bottom electrode along a direction toward the top electrode is nonhomogeneous.

6. The RRAM structure of claim 1, further comprising:
a dielectric layer disposed under the RRAM; and
a titanium plug embedded in the dielectric layer, wherein the titanium plug contacts the bottom electrode.

7. The RRAM structure of claim 6, wherein the bottom electrode is monolithic.

8. The RRAM structure of claim 6, wherein the titanium plug directly contacts the dielectric layer.

9. The RRAM structure of claim 6, wherein the titanium plug is T-shaped.

10. The RRAM structure of claim 1, wherein the variable resistive layer comprises tantalum oxide or hafnium oxide.

11. The RRAM structure of claim 1, wherein 0<x≤2.

12. A fabricating method of a resistive random access memory (RRAM) structure, comprising:
forming an RRAM, wherein the RRAM comprises a bottom electrode, a variable resistive layer and a top electrode stacked from bottom to top, wherein the bottom electrode is composed of titanium oxide (TiOₓ), and x has an increased gradient variation which is increased toward the top electrode.

13. The fabricating method of the RRAM structure of claim 12, wherein the increased gradient variation is increased in a unit that is not an integer.

14. The fabricating method of the RRAM structure of claim 12, wherein the increased gradient variation is increased in a continuous manner.

15. The fabricating method of the RRAM structure of claim 12, wherein the increased gradient variation is increased linearly or curvedly.

16. The fabricating method of the RRAM structure of claim 12, wherein a composition of the bottom electrode along a direction toward the top electrode is nonhomogeneous.

17. The fabricating method of the RRAM structure of claim 12, further comprising:
a dielectric layer disposed under the RRAM; and
a titanium plug embedded in the dielectric layer, wherein the titanium plug contacts the bottom electrode.

18. The fabricating method of the RRAM structure of claim 17, wherein the bottom electrode is monolithic.

19. The fabricating method of the RRAM structure of claim 17, wherein the titanium plug directly contacts the dielectric layer.

20. The fabricating method of the RRAM structure of claim 17, wherein the titanium plug is T-shaped.

21. The fabricating method of the RRAM structure of claim 12, wherein the variable resistive layer comprises tantalum oxide or hafnium oxide.

22. The fabricating method of the RRAM structure of claim 12, wherein 0<x≤2.
